(19) United States
(12) Patent Application Publication
(10) Pub. No.: US 2007/0164326 A1
(43) Pub. Date: Jul. 19, 2007

(54) Field effect transistor

(76) Inventors: Yasuhiro Okamoto, Minato-ku (JP); Yuji Ando, Minato-ku (JP); Hironobu Miyamoto, Minato-ku (JP); Tatsuo Nakayama, Minato-ku (JP); Takashi Inque, Minato-ku (JP); Masaaki Kuzuhara, Minato-ku (JP)

Correspondence Address: SUGHRUE MION, PLLC, 2100 PENNSYLVANIA AVENUE, N.W., SUITE 800, WASHINGTON, DC, 20037, US

(21) Appl. No.: 10/588,775

(22) PCT Filed: Feb. 21, 2005
(86) PCT No.: PCT/JP05/02712

§ 371 Date: Aug. 8, 2006

(30) Foreign Application Priority Data
Feb. 20, 2004 (JP) 2004-044459

(51) Int. Cl. H01L 29/76

(52) U.S. Cl. 257/288

(57) ABSTRACT

A field effect transistor includes a semiconductor layer structure including GaN channel layer 12 and AlGa electron supply layer 13, source electrode 1 and drain electrode 3 which are formed on electron supply layer 13 so as to be separated from each other, gate electrode 2 formed between source electrode 1 and drain electrode 3, and SiON film 23 formed on electron supply layer 13. Gate electrode 2 has a field plate portion 5 that projects toward drain electrode 3 in the form of an eave on SiON film 23. The thickness of a portion (field plate layer 23a) of SiON film 23 lying between field plate portion 5 and electron supply layer 13 gradually increases from gate electrode 2 to drain electrode 3.

### FIELD EFFECT TRANSISTOR

1. Technical Field

The present invention relates to a field effect transistor using a III group nitride semiconductor.

2. Background Art

FIG. 1 is a cross-sectional structure view of a conventional Hetero-Junction Field Effect Transistor (hereinafter, referred to “HJFET”). Such a conventional HJEFT is reported in “Y Ando, 2001, International Electron Device Meeting Digest (IEDM01-381 to 384)”.

In the conventional HJFET shown in FIG. 1, AlN buffer layer 111, GaN channel layer 112, and AlGaN electron supply layer 113 are laminated on sapphire substrate 109 in this order. Also, source electrode 101 and drain electrode 103 are formed on AlGaN electron supply layer 113, and these electrodes 101, 103 are in ohmic contact with AlGaN electron supply layer 113. Further, gate electrode 102 is formed between source electrode 101 and drain electrode 103, and gate electrode 102 is in Schottky contact with AlGaN electron supply layer 113. At the uppermost layer of this HJFET, SiN film 121 is formed as a surface passivation film.

In such an AlGaN/GaN HJFET, a trade-off exists between the amount of collapse and the gate breakdown voltage, and it is very difficult to control the trade-off. In the AlGaN/GaN Hetero-Junction, piezo-polarization occurs by stress caused by lattice mismatch between the AlGaN layer and the GaN layer, two-dimensional electron gas is supplied to the AlGaN/GaN interface. Therefore, when a passivation film that causes a stress in a device surface is formed, the device characteristic of HJFET is influenced.

FIG. 2 is a graph showing a relationship among the thickness of surface passivation film SiN, the amount of change of electric current caused by collapse, and the gate breakdown voltage.

In this description, the collapse is a phenomenon in which, during the large signal operation of HJFET, negative charges are accommodated in the surface in response to the surface trap and the maximum drain current is suppressed. When the collapse becomes pronounced, the drain current is suppressed during large signal operation, and therefore the saturation power is lowered.

The SiN film is formed on the surface of the device with pronounced such a collapse, the piezo-polarization charges in AlGaN increase by the stress of the SiN film to counter the surface negative charges, and therefore the amount of collapse can be reduced. Referring to FIG. 2, for example, the amount of collapse is 60% or more when there is no SiN film (film thickness Onm), whereas the amount of collapse can be suppressed to 10% or less when the film thickness of the SiN film is 100 nm.

On the other hand, the surface negative charges reduce the electric field concentration to the gate edge and enhance the gate breakdown voltage. Therefore, when the SiN film is made thicker to counter the surface negative charges, the electric field concentration to the gate edge becomes pronounced, and the gate breakdown voltage is lowered. Accordingly, as shown in FIG. 2, the trade-off caused by the thickness difference of the SiN film that exists between the collapse and the gate breakdown voltage.

FIG. 3 is a cross-sectional structure view of another conventional HJFET to which a field plate portion is added in order to solve the problems in the above-mentioned HJFET Such a conventional HJFET is reported in “Li, et al. 2001 Electronics Letters vol. 37 p. 196-197”.

This HJFET is formed on substrate 110 made of SiC or the like. Buffer layer 111 made of a semiconductor layer is formed on substrate 110. GaN channel layer 112 is formed on buffer layer 111. AlGaN electron supply layer 113 is formed on the channel layer. Source electrode 101 and drain electrode 103 that are in ohmic contact are arranged on electron supply layer 113. Between source electrode 101 and drain electrode 103, field plate portion 105 projecting toward drain electrode 103 in the form of an eave is arranged and gate electrode 102 is arranged in Schottky contact. The surface of electron supply layer 113 is covered with SiN film 121, and SiN film 121 exits directly underneath field plate portion 105.

As described above, according to the HJFET to which the field plate portion is added, the trade-off between the collapse and gate breakdown voltage can be improved. Specifically, the electric field near the gate is reduced by the field plate portion in pinch-off state during the large signal operation, thereby improving the gate breakdown voltage, and the surface electric potential is modulated by the field plate portion in off-state, thereby applying the maximum drain current.

As explained with reference to FIGS. 1 and 2, when the SiN film is formed on the surface of the device with the pronounced collapse, the piezo-polarization charges in AlGaN increase by the stress of the SiN film to counter the surface negative charges, however, when the SiN film is made thicker to counter the surface negative charges, the electric field concentration between gate and drain becomes pronounced and the gate breakdown voltage is lowered.

Therefore, like the conventional art shown in FIG. 3, it is proposed that the field plate portion be arranged between the source electrode and the drain electrode, however, because the thickness of the SiN film directly underneath the field plate portion is thicker, no sufficient electric field reduction effect can be obtained. In the conventional field plate structure shown in FIG. 3, it is possible to attain simultaneous pursuit of the gate breakdown voltage and the suppression of collapse, which are required at the operating voltage of about 30V, however, it is difficult to attain simultaneous pursuit of the gate breakdown voltage and the suppression of collapse, which are required for the operation at higher voltage, 50V or more.

The larger size of the field plate, the greater effect of collapse suppression, and therefore the effect of collapse suppression can be further obtained by increasing the size of the field plate. However, when the size of the field plate exceeds 70% of the interval between the gate electrode and the drain electrode, the gate breakdown voltage is adversely apt to be lowered because the gate breakdown voltage is determined by the electric field concentration to the field plate edge. Therefore, there is a limit to the effect that collapse suppression can have by increasing the size of the field plate.

### DISCLOSURE OF INVENTION

The object of the present invention is to provide a field effect transistor that can attain simultaneous pursuit of gate breakdown voltage and collapse suppression, which is required to carry out an operation at a higher voltage.

To achieve the above object, a field effect transistor of the present invention includes a III group nitride semiconductor layer structure including hetero junction, a source electrode and a drain electrode that are so formed on said semiconductor layer structure as to be separated from each other, a gate electrode formed between the source electrode and said drain electrode, and an insulating film formed on the semiconductor layer structure: the gate electrode has a field plate portion that projects to the drain electrode in the form of an eave and is formed on the insulating film; and the thickness of a portion of the insulating film lying between the field plate portion and the semiconductor layer structure gradually increases from the gate electrode toward the drain electrode.

According to the field effect transistor of the present invention, by arranging the field plate portion, the electric field applied to the end portion of the gate electrode at the side of drain electrode is reduced by the operation of the field plate portion when a high reverse voltage is applied between gate and drain, and therefore the gate breakdown voltage is improved. Further, during the large signal operation, in particular, the surface potential immediately near the gate is effectively modulated by the field plate portion, and therefore collapse in response to the surface trap can be prevented from occurring.

Moreover, according to the field effect transistor of the present invention, because the thickness of the insulating film in the area near the gate electrode, where the electric field is most concentrated, i.e., the insulating film directly underneath the field plate portion, gradually increases from the gate electrode toward the drain electrode, the film thickness of the insulating film in that area becomes thinner the insulating film in the other area, the electric field concentration is reduced both by operations of the surface negative charges and the field plate portion in this area, and the gate breakdown voltage can be improved. Incidentally, though the surface negative charges cause the collapse, the surface negative charges are generated immediately near the gate electrode and the surface potential can be effectively modulated by field plate portion 5 since the insulating film at the area near the gate electrode is relatively thin. Therefore, the collapse can be suppressed.

As described above, according to the field effective transistor of the present invention, simultaneous pursuit of the gate breakdown voltage and the collapse suppression can be further excellently attained, and the operation at a higher voltage can be carried out than the conventional one.

Further, the semiconductor layer structure may have an AlGaN/GaN hetero structure.

Further, the thickness of the portion of the insulating film may vary stepwise, or the thickness of the portion of the insulating film may vary continuously.

Also, the insulating film may be a SiON film, a SiO₂ film, or a SiN film or a laminated layer of a SiN film and a SiO₂ film.

Further, the drain field plate electrode connected to the drain electrode may be arranged on the insulating film between the gate electrode and the drain electrode. According to this arrangement, since the electric field concentration at the end of the drain electrode can be reduced by the drain field plate electrode, the breakdown voltage characteristic can be improved and operation at higher voltage can be performed, in comparison with the arrangement having only the field plate at the side of gate electrode. Also, because the influence on gain lowering is larger in the field plate at the side of gate electrode, the drain field plate electrode is arranged so as to shorten the field plate at the side of gate electrode, whereby the gain can be improved while the breakdown voltage characteristic is maintained.

### BRIEF DESCRIPTION OF THE DRAWINGS

FIG. 1 is a cross-sectional structure view of a conventional hetero junction field effect transistor.

FIG. 2 is a graph showing a relationship among the thickness of surface passivation film SiN, the current change amount by the collapse, and the gate breakdown voltage.

FIG. 3 is a cross-sectional structure view of another conventional HJFET to which a field plate portion is added.

FIG. 4 is a cross-sectional structure view of a HJFET according to the first embodiment of the present invention.

FIG. 5 is a cross-sectional structure view of a HJFET according to the second embodiment of the present invention.

FIG. 6 is a cross-sectional structure view of a modified example of the HJFET shown in FIG. 5.

FIG. 7 is a cross-sectional structure view of a HJFET according to the third embodiment of the present invention.

FIG. 8 is a cross-sectional structure view of a modified example of the HJFET shown in FIG. 7.

FIG. 9 is a cross-sectional structure view of a modified example of the HJFET shown in FIG. 7.

FIG. 10 is a cross-sectional structure view of a modified example of the HJFET shown in FIG. 7.

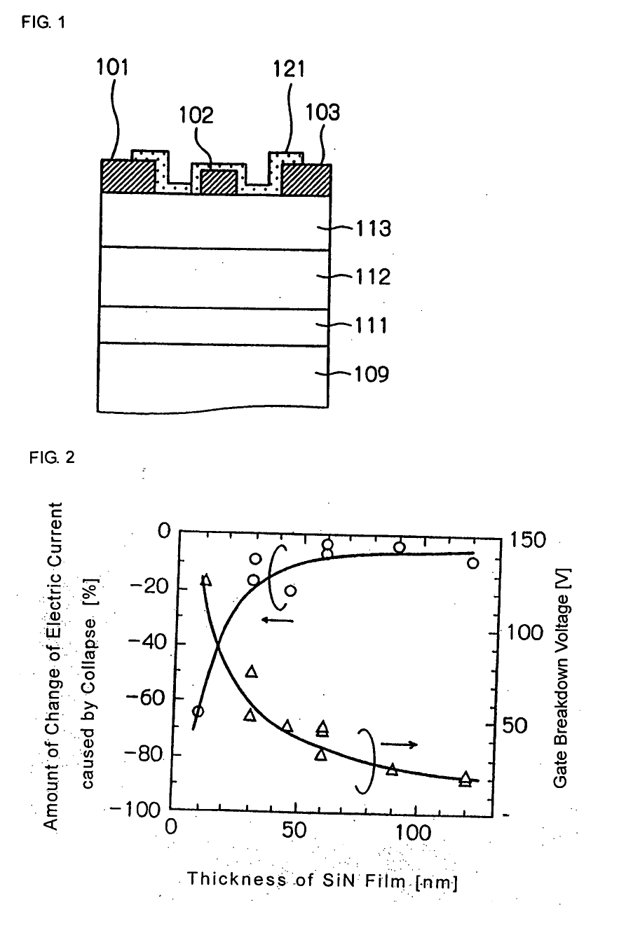

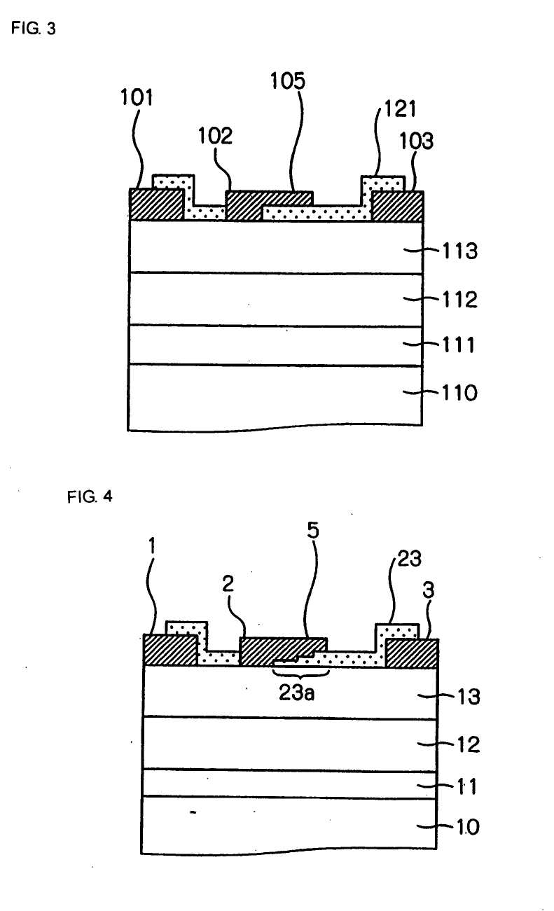

### BEST MODE FOR CARRYING OUT THE INVENTION

Embodiments of the present invention are explained with reference to drawings.

### First Embodiment

FIG. 4 is a cross-sectional structure view of a HJFET according to the first embodiment of the present invention.

The HJFET according to the first embodiment is formed on substrate 10 made of SiC or the like. Buffer layer 11 made of semiconductor is formed on substrate 10. GaN channel layer 12 is formed on buffer layer 11. AlGaN electron supply layer 13 is formed on GaN channel layer 12. Source electrode 1 and drain electrode 3 that are in ohmic contact are arranged on AlGaN electron supply layer 13. Field plate portion 5 that projects toward drain electrode 3 in the form of an eave is arranged between source electrode 1 and drain electrode 3 and gate electrode 2 is arranged in Schottky contact. The surface of AlGaN electron supply layer 13 is covered with SiON film 23, which is an insulating film, and SiON film 23 directly underneath field plate portion 5 (field plate layer 23a) becomes thicker stepwise from gate electrode 2 to drain electrode 3.

The HJFET of the first embodiment is manufactured, as follows.

First, a semiconductor is grown on substrate 10 of SiC or the like, for example, by the Molecular Beam Epitaxy (MBE). The semiconductor layer formed like this, includes buffer layer 11 (film thickness 20 nm) made of undoped AlN, channel layer 12 (film thickness 2 μm) made of undoped GaN, and AlGaN supply layer 13 (film thickness 25 nm) made of undoped Al_{0.2}Ga_{0.8}N, in order from substrate 10.

Then, a part of the epitaxial layer structure is etched until GaN channel layer 12 is exposed, whereby an isolation mesa (not shown) is formed. Successively, metal, like Ti/Al, is deposited on AlGaN electron supply layer 13 to form source electrode 1 and drain electrode 3, and annealing at 650° C. is performed to be in ohmic contact.

Then, SiON film 23 (film thickness 150 nm) is formed by the plasma CVD method or the like. The film thickness of field plate layer 23a, which is a position covered by field plate portion 5 in SiON film 23, is varied stepwise by etching, and metal, like Ni/Au, is deposited on AlGaN electron supply layer 13, which is completely removed to be exposed, to form gate electrode 2 that is in Schottky contact and has field plate portion 5. In the first embodiment, as shown in FIG. 4, the thickness of field plate layer 23a is varied so as to be gradually thicker from gate electrode 2 to drain electrode 3 in three steps.

In this way, the HJFET shown in FIG. 4 is manufactured.

Field plate portion 5 is arranged, as in the first embodiment, the electric field that is applied to the end portion of gate electrode 2 at the side of drain electrode 3 is reduced by the operation of field plate portion 5, when a high reverse voltage is applied between gate-drain, and therefore the gate breakdown voltage is improved. Further, during the large signal operation, in particular, the surface potential immediately near the gate is effectively modulated by field plate portion 5, and therefore, collapse in response to the surface trap can be prevented from occurring.

Additionally, according to the first embodiment, SiON film 23 in the area near gate electrode 2, where the electric field is most concentrated, i.e., field plate layer 23a, which is SiON film 23 directly underneath field plate portion 5, is made thinner than other areas of SiON film 23, whereby the electric field concentration in this area is reduced both by operations of the surface charges and the field plate portion 5, and the gate breakdown voltage can be improved. Incidentally, though the surface negative charges cause the collapse, surface negative charges are generated just near gate electrode 2 and the surface potential can be effectively modulated by field plate portion 5 since field plate layer 23a is relatively thin. Therefore, collapse can be suppressed.

In the structure in which the thickness of field plate layer 23a is varied stepwise, as in the first embodiment, the size of the thinnest portion (the portion at the first step) of field plate layer 23a in the direction extending between gate electrode 2 and drain electrode 3 is preferably 0.3 μm or more. Further, the size of thinnest portion of field plate layer 23a is preferably 0.5 μm or more. Also, the entire size of field plate portion 5, that extends to drain electrode 3 is preferably 0.5 μm or more, and the entire size of field plate portion 5 is preferably 0.7 μm or more. Also, the end portion of field plate portion 5 is positioned so as not to overlap with drain electrode 3.

As the size of field plate portion 5 is enlarged, the effect of collapse suppression is increased, however, the gate breakdown voltage is determined by the electric field concentration between field plate portion 5 and drain electrode 3, and therefore, when the end portion of field plate portion 5 at the side of drain electrode 3 exceeds 70% of the interval between gate electrode 2 and drain electrode 3, the gate breakdown voltage is adversely apt to be lowered. Therefore, the size of field plate portion 5 is preferably set to 70% or less of the interval between gate electrode 2 and drain electrode 3.

In the first embodiment, the thickness of field plate layer 23a, which is SiON film 23 directly underneath field plate portion 5, is gradually varied to be thicker in three steps from gate electrode 2 to drain electrode 3, however, the same effect can be obtained when the thickness is varied at least in two steps. The example that uses the SiO film as the insulating film to form field plate layer 23a is shown in the first embodiment. The same effect can be obtained when SiN film, SiO₂ film or a laminated layer of SiN film and SiO₂ film may be used instead of SiON film.

### Second Embodiment

FIG. 5 is a cross-sectional structure view of a HJFET according to the second embodiment of the present invention.

The HJFET according to the second embodiment is formed on substrate 10 made of SiC or the like. Buffer layer 11 made of semiconductor is formed on substrate 10. GaN channel layer 12 is formed on buffer layer 11. AlGaN electron supply layer 13 is formed on GaN channel layer 12. Source electrode 1 and drain electrode 3 are arranged on AlGaN electron supply layer 13 in ohmic contact. Between source electrode 1 and drain electrode 3, field plate portion 5 that projects toward drain electrode 3 in the form of an eave is arranged and gate electrode 2 is arranged in Schottky contact. The surface of AlGaN electron supply layer 13 is covered with SiON film 23, which is an insulating film, and SiON film 23 directly underneath field plate portion 5 (field plate layer 23a) becomes thicker continuously from gate electrode 2 to drain electrode 3.

The HJFET of the second embodiment is manufactured, as follows.

First, semiconductor is grown on substrate 10 of SiC or the like, for example, by the Molecular Beam Epitaxy (MBE). The semiconductor layer formed like this, includes buffer layer 11 (film thickness 20 nm) made of undoped AlN, channel layer 12 (film thickness 2 μm) made of undoped GaN, and AlGaN supply layer 13 (film thickness 25 nm) made of undoped Al_{0.2}Ga_{0.8}N, in order from substrate 10.

Then, a part of the epitaxial layer structure is etched until GaN channel layer 12 is exposed, whereby an isolation mesa (not shown) is formed. Successively, metal, like Ti/Al, is deposited on AlGaN electron supply layer 13 to form source electrode 1 and drain electrode 3, and annealing at 650° C. is performed to be in ohmic contact.

Then, SiON film 23 (film thickness 150 nm) is formed by the plasma CVD method or the like. Field plate layer 23a is formed such that the film thickness continuously increases from gate electrode 2 to drain electrode 3 by etching a portion covered by field plate portion 5 in SiON film 23 in tapered form, a part of AlGaN electron supply layer 13 is exposed, and metal, like Ni/Au, is deposited on exposed AlGaN electron supply layer 13, to form gate electrode 2 that is in Schottky contact and has field plate portion 5.

In this way, the HJFET shown in FIG. 5 is manufactured.

Field plate portion 5 is also arranged in the second embodiment, the electric field applied to the end portion of gate electrode 2 at the side of drain electrode 3 is reduced by the operation of field plate portion 5, when a high reverse voltage is applied between gate and drain, and therefore the gate breakdown voltage is improved. Further, during the large signal operation, in particular, the surface potential immediately near the gate is effectively modulated by field plate portion 5, and therefore, collapse in response to the surface trap can be prevented from occurring.

Additionally, SiON film 23 in the area near gate electrode 2, where the electric field is most concentrated, i.e., field plate layer 23a, which is SiON film 23 directly underneath field plate portion 5, is made thinner than other areas of SiON film 23, whereby the electric field concentration in this area is reduced both by operations of the surface charges and the field plate portion 5, and the gate breakdown voltage can be improved. Incidentally, though the surface negative charges cause the collapse, surface negative charges are generated immediately near gate electrode 2 and the surface potential can be effectively modulated by field plate portion 5 since field plate layer 23a is relatively thin. Therefore, the collapse can be suppressed.

In the structure of the second embodiment in which the thickness of field plate layer 23a is continuously varied, the size of the area where the thickness of field plate layer 23a varies in the direction that extends between gate electrode 2 and drain electrode 3 is preferably 0.3 μm or more. Further, the size of the area where the thickness of field plate layer 23a varies, is preferably 0.5 μm or more. Also, the end portion of field plate portion 5 is positioned so as not to overlap with drain electrode 3. Further, due to the same reason explained in the first embodiment, the size of field plate portion 5 is preferably 70% or less of the interval between gate electrode 2 and drain electrode 3.

In the second embodiment, the thickness of field plate layer 23a is varied across all areas directly underneath field plate portion 5, however, the same effect can be obtained, as long as the thickness of field plate layer 23a is varied at least at a part directly underneath field plate portion 5. Also, in the second embodiment, field plate portion 5 projects toward drain electrode 3 in the form of an eave, however, field plate portion 5 may project toward source electrode 1 in the form of an eave. Also, in the second embodiment, the example that uses the SiO film as the insulating film to form field plate layer 23a is shown. The same effect can be obtained when SiN film, SiO₂ film or a laminated layer of SiN film and SiO₂ film may be used instead of SiON film.

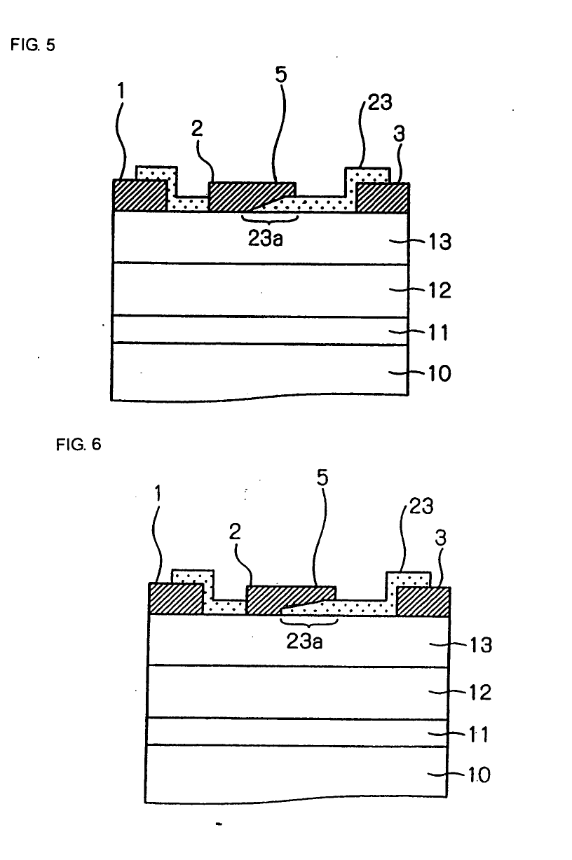

FIG. 6 is a cross-sectional structure view of a modified example of the HJFET shown in FIG. 5. Field plate layer 23a in the second embodiment is extremely thin at the end portion of gate electrode 2, however, as shown in FIG. 6, field plate layer 23a is varied in thickness underneath field plate portion 5 while constant thickness is ensured near gate electrode 2. According to this arrangement, the gain can be improved near gate electrode 2 by capacity reduction and the breakdown voltage caused by the breakage of field plate layer 23a can be improved. The thickness of field plate layer 23a near the gate electrode is preferably 10 nm or more, and is further preferably 50 nm or more.

### Third Embodiment

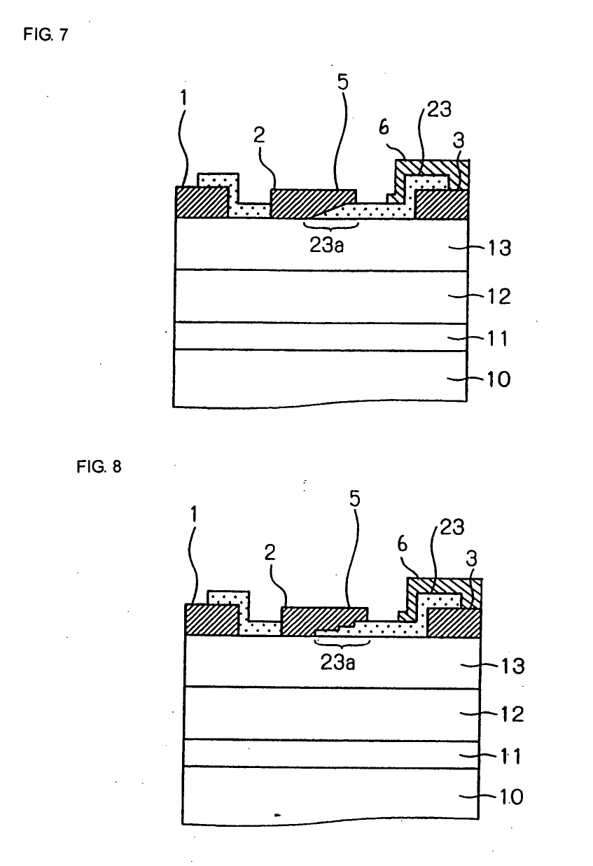

FIG. 7 is a cross-sectional structure view of a HJFET according to the third embodiment of the present invention.

The HJFET according to the third embodiment is formed on substrate 10 made of SiC or the like. Buffer layer 11 made of a semiconductor is formed on substrate 10. GaN channel layer 12 is formed on buffer layer 11. AlGaN electron supply layer 13 is formed on GaN channel layer 12. Source electrode 1 and drain electrode 3 are arranged on AlGaN electron supply layer 13 in ohmic contact. Between source electrode 1 and drain electrode 3, field plate portion 5 that projects toward drain electrode 3 in the form of an eave is arranged and gate electrode 2 is arranged in Schottky contact. The surface of electron supply layer 13 is covered with SiON film 23, which is an insulating film, and SiON film 23 that is directly underneath field plate portion 5 (field plate layer 23a) becomes thicker continuously from gate electrode 2 to drain electrode 3. Also, drain filed plate electrode 6 connected to drain electrode 3 is arranged on SiON film 23 between gate electrode 2 and drain electrode 3.

The HJFET of the third embodiment is manufactured, as follows.

First, semiconductor is grown on substrate 10 of SiC or the like, for example, by the Molecular Beam Epitaxy (MBE). The semiconductor layer formed like this, includes buffer layer 11 (film thickness 20 nm) made of undoped AlN, channel layer 12 (film thickness 2 μm) made of undoped GaN, and AlGaN supply layer 13 (film thickness 25 nm) made of undoped Al_{0.2}Ga_{0.8}N, in order from substrate 10.

Then, a part of the epitaxial layer structure is etched until GaN channel layer 12 is exposed, whereby an isolation mesa (not shown) is formed. Successively, metal, like Ti/Al, is deposited on AlGaN electron supply layer 13 to form source electrode 1 and drain electrode 3, and annealing at 650° C. is performed to be in ohmic contact.

Then, SiON film 23 (film thickness 150 nm) is formed by the plasma CVD method or the like. Field plate layer 23a is formed such that the film thickness continuously increases from gate electrode 2 to drain electrode 3 by etching a portion covered by field plate portion 5 in SiON film 23 in tapered form, a part of AlGaN electron supply layer 13 is exposed, and metal, like Ni/Au, is deposited on exposed AlGaN electron supply layer 13, to form gate electrode 2 that is in Schottky contact and has field plate portion 5. After that, a part of SiON film 23 on drain electrode 3 is removed by etching, and metal, like Ti/Au, is deposited to form drain field plate electrode 6.

In this way, the HJFET shown in FIG. 7 is manufactured.

According to the arrangement of the third embodiment, since the electric field concentration at the end of drain electrode 3 can be reduced by drain field plate electrode 6, the breakdown voltage characteristic can be improved and operation at a higher voltage can be performed, in comparison with arrangements having only field plate 5 at the side of gate electrode 2, as in the first and second embodiments. Also, because field plate 5 at the side of gate electrode 2 has a larger influence on gain lowering, drain field plate electrode 6 is arranged to shorten field plate 5, as in the third embodiment, whereby the gain can be improved while the breakdown voltage characteristic is maintained.

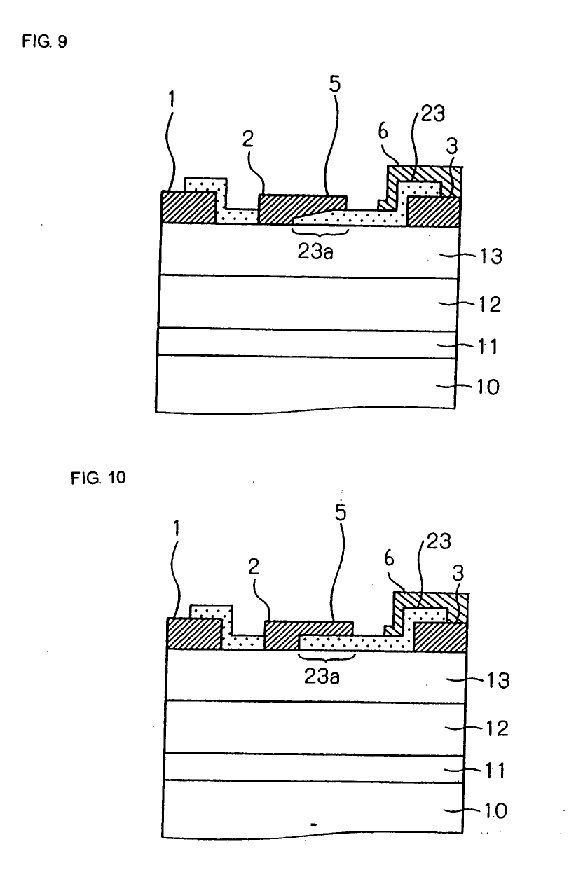

FIG. 8 is a cross-sectional structure view of a modified example of the HJFET shown in FIG. 7. Drain field plate electrode 6 in the third embodiment is also available to HJFET in which SiON film 23 that is directly underneath field plate 5 (field plate layer 23a) becomes thicker stepwise from gate electrode 2 to drain electrode 3, as shown in FIG. 8. FIG. 9 is a cross-sectional structure view of another modified example of the HJFET shown in FIG. 7. Drain field plate electrode 6 in the third embodiment is also available to HJFET in which field plate layer 23a near gate electrode 2 ensures a constant thickness, as shown in FIG. 9. Further, drain field plate electrode 6 is also available to HJFET in which field plate layer 23a does not vary in thickness, as shown in FIG. 10.

1. A field effect transistor comprising a III group nitride semiconductor layer structure including hetero junction, a source electrode and a drain electrode that are so formed on said semiconductor layer structure as to be separated each other, a gate electrode formed between said source electrode and said drain electrode, and an insulating film formed on said semiconductor layer structure, characterized in that
said gate electrode has a field plate portion that projects to said drain electrode in the form of an eave and that is formed on said insulating film; and
thickness of a portion of said insulating film lying between said field plate portion and said semiconductor layer structure gradually increases from said gate electrode toward said drain electrode.

2. The field effect transistor according to claim 1, wherein said semiconductor layer structure has an AlGaN/GaN hetero structure.

3. The field effect transistor according to claim 1, wherein a thickness of said portion of said insulating film varies stepwise.

4. The field effect transistor according to claim 1, wherein a thickness of said portion of said insulating film varies continuously.

5. The field effect transistor according to anyone of claims 1, wherein said insulating film is a SiON film.

6. The field effect transistor according to anyone of claims 1, wherein said insulating film is a SiO2 film or a SiN film.

7. The field effect transistor according to anyone of claims 1 wherein said insulating film is a laminated layer of a SiO2 film and a SiN film.

8. The field effect transistor according to anyone of claims 1, wherein a drain field plate electrode connected to said drain electrode is arranged on said insulating film between said gate electrode and said drain electrode.
